(19) United States
(12) Patent Application Publication
(10) Pub. No.: US 2018/0123507 A1
(43) Pub. Date: May 3, 2018

(54) PHOTOVOLTAIC PACKAGE AND METHOD OF MANUFACTURING THE SAME

(71) Applicant: KOREA INSTITUTE OF ENERGY RESEARCH, Daejeon (KR)

(72) Inventors: Young-joo EO, Daejeon (KR); Jun-sik CHO, Daejeon (KR); Jae-ho YUN, Daejeon (KR); Se-jin AHN, Daejeon (KR); Jihye GWAK, Daejeon (KR); Jin-su YOO, Daejeon (KR); Seung-kyu AHN, Daejeon (KR); Joo-hyung PARK, Daejeon (KR); Ara CHO, Daejeon (KR); Kihwan KIM, Daejeon (KR)

(21) Appl. No.: 15/675,791

(22) Filed: Aug. 14, 2017

(30) Foreign Application Priority Data
Oct. 27, 2016 (KR) 10-2016-0141091

(51) Int. Cl. H02S 40/10; H01L 31/049

(52) U.S. Cl. CPC H02S 40/10; H01L 31/049

(57) ABSTRACT

Disclosed is a photovoltaic package having a simple structure configured to enable mid-term or short-term use thereof, the photovoltaic package including a photovoltaic cell for producing electrical energy through photoelectric conversion, a front sealing sheet disposed on the front side of the photovoltaic cell, and a back sealing sheet disposed on the back side of the photovoltaic cell, wherein at least one of the front sealing sheet and the back sealing sheet contains therein moisture-absorbent particles, and the front sealing sheet and the back sealing sheet are adhered to each other so that the photovoltaic cell is sealed.

### CROSS-REFERENCE TO RELATED APPLICATION

This application claims the priority benefit of Korean Patent Application No. 10-2016-0141091, filed on Oct. 27, 2016 in the Korean Intellectual Property Office, the disclosure of which is incorporated herein by reference.

This research was supported by the Technology Development Program to Solve Climate Changes of the National Research Foundation (NRF) funded by the Ministry of Science, ICT & Future Planning (NRF-2016M1A2A2936753). This work was also conducted partly under the framework of the Research and Development Program of the Korea Institute of Energy Research (KIER) (B7-2421). Further, this work was supported by the Korea Institute of Energy Technology Evaluation and Planning (KETEP) and the Ministry of Trade, Industry & Energy (MOTIE) of the Republic of Korea (No. 20163030013760).

### BACKGROUND OF THE INVENTION

### 1. Technical Field

The present invention relates to a photovoltaic package and a method of manufacturing the same, and more particularly to a photovoltaic package having a simple structure compared to typical photovoltaic modules and a method of manufacturing the same.

### 2. Description of the Related Art

Typically, a solar cell is a photoelectric conversion device for converting light energy into electrical energy, which is configured such that electrical energy resulting from the production and separation of electric charges generated at P-N junctions is collected and supplied to the outside.

Such a solar cell is used outdoors in order to absorb light energy, and thus suffers from gradually decreased power generation efficiency owing to the deterioration of the solar cell, which is responsible for photoelectric conversion, and the conductor for transferring electric power. Owing to such problems, the solar cell is not used as it is, but is protected by packaging the outside of a photovoltaic cell in various materials, and such a structure is referred to as a “photovoltaic module”. Furthermore, a photovoltaic element provided in such a photovoltaic module may be called a photovoltaic cell in order to differentiate it from the photovoltaic module.

Such a photovoltaic module is typically configured such that a front sheet made of glass, which is a transparent protective member on the surface thereof, and a back sheet, which is a protective member at the back thereof, are provided, between which two encapsulation sheets are interposed to enclose a photovoltaic cell. The photovoltaic module is manufactured in a manner in which the front sheet, the first encapsulation sheet, the photovoltaic cell, the second encapsulation sheet and the back protective film are sequentially stacked and the resulting stack is heated and pressed so that the encapsulation sheets are crosslinked and cured to thus adhere and integrate the stack (Korean Patent No. 10-1343884).

In the photovoltaic module, protecting the photovoltaic cell from moisture is regarded as important, and various configurations for increasing the moisture absorption capability thereof are under study, but are complicated, and thus the manufacturing costs may increase (Korean Patent Application Publication No. 10-2015-0127138 and Korean Patent No. 10-1561892).

In particular, since an expensive monocrystalline silicon solar cell having excellent photoelectric conversion efficiency has been conventionally used, many attempts are being made to protect a photovoltaic cell in order to increase the lifetime thereof, and photovoltaic modules for large-capacity power generation are mainly developed, and thus the application range thereof is not wide. Furthermore, the subsequent development of solar cells using inexpensive compound semiconductors may decrease photovoltaic cell manufacturing costs, but costs incurred during the formation of the photovoltaic module are still high, and hence, the range of use of solar cells is still limited.

### SUMMARY OF THE INVENTION

Accordingly, the present invention has been made keeping in mind the problems encountered in the related art, and the present invention is intended to provide a photovoltaic package, which is simply configured to protect a photovoltaic cell to thus enable mid-term or short-term use thereof, and a method of manufacturing the same.

Therefore, the present invention provides a photovoltaic package, comprising: a photovoltaic cell for producing electrical energy through photoelectric conversion; a front sealing sheet disposed on the front side of the photovoltaic cell; and a back sealing sheet disposed on the back side of the photovoltaic cell, wherein at least one of the front sealing sheet and the back sealing sheet contains therein moisture-absorbent particles, and the front sealing sheet and the back sealing sheet are adhered to each other to seal the photovoltaic cell.

As the use of portable electronic devices, particularly portable smart devices, such as smartphones and tablet PCs, is recently increasing, the frequency of use of auxiliary batteries for charging portable electronic devices is also increasing. However, such auxiliary batteries themselves have to be pre-charged due to the use of secondary batteries and the charge amount thereof is limited, and thus, limitations are imposed on the use thereof. Unlike secondary batteries, solar cells are able to continuously generate power in the presence of light, but it is difficult to use them across a wide range of applications due to the high cost of configuration of photovoltaic modules.

Accordingly, the present invention provides a photovoltaic package having a simple packaging structure with moisture absorption capability, and thereby provides an inexpensive photovoltaic power generation system suitable for mid-term or short-term use. Such a photovoltaic package may be manufactured at very low cost and may thus be employed in a variety of applications such as portable auxiliary batteries or promotional items.

Here, the moisture-absorbent particles may include silica gel. When the particle size of the moisture-absorbent particles is 100 μm or less, light incident on the photovoltaic cell is not excessively dispersed. Furthermore, when the volume of the moisture-absorbent particles contained in the front sealing sheet or the back sealing sheet is 30% or less of the volume of the front sealing sheet or the back sealing sheet, the properties of the front sealing sheet or the back sealing sheet are not deteriorated.

Also, the moisture-absorbent particles may be contained in both the front sealing sheet and the back sealing sheet. Here, when the particle size of the moisture-absorbent particles contained in the back sealing sheet is greater than the particle size of the moisture-absorbent particles contained in the front sealing sheet, light may be incident on the front sealing sheet at high efficiency. The particle size of the moisture-absorbent particles contained in the back sealing sheet is preferably set to the range of 500 μm or less.

Also, at least one of the front sealing sheet and the back sealing sheet may contain wavelength conversion particles. Preferably, the wavelength conversion particles are contained in the front sealing sheet, or the wavelength conversion particles are contained in both the front sealing sheet and the back sealing sheet. The wavelength conversion particles function to convert the wavelength of incident light into a wavelength range within which the power generation efficiency of the photovoltaic cell is high, thereby increasing the power generation efficiency of the photovoltaic package.

Also, when the moisture-absorbent particles are contained in only the back sealing sheet and the wavelength conversion particles are contained in the front sealing sheet, improvements in power generation efficiency attributable to wavelength conversion may be obtained while maintaining moisture absorption capability.

Both the front sealing sheet and the back sealing sheet are made of EVA (Ethylene-Vinyl Acetate), and the front sealing sheet and the back sealing sheet may be thermally adhered to each other.

In addition, the present invention provides a method of manufacturing a photovoltaic package configured such that a photovoltaic cell is packaged, the method comprising: a preparation step of providing a photovoltaic cell for producing electrical energy through photoelectric conversion and a front sealing sheet and a back sealing sheet for sealing the photovoltaic cell; a disposition step of sequentially stacking and disposing the back sealing sheet, the photovoltaic cell and the front sealing sheet; and a sealing step of sealing the photovoltaic cell by adhering the back sealing sheet and the front sealing sheet to each other, wherein, in the preparation step, moisture-absorbent particles are added during at least one of manufacturing the front sealing sheet and manufacturing the back sealing sheet.

Here, in the sealing step, the back sealing sheet and the front sealing sheet are preferably thermally adhered. For thermal adhesion, the back sealing sheet and the front sealing sheet may be manufactured using EVA in the preparation step.

Alternatively, in the sealing step, the back sealing sheet and the front sealing sheet may be adhered using an adhesive member, and the adhesive member may include a thermal adhesive such as an EVA adhesive, etc., or a tacky adhesive.

According to the present invention, a photovoltaic cell is sealed using sealing sheets having moisture-absorbent particles dispersed therein. Despite a simple structure in which packaging is performed using only the sealing sheets, the photovoltaic cell can be protected from moisture by means of the moisture-absorbent particles, thereby enabling mid-term or short-term use of a photovoltaic package.

Compared to conventional photovoltaic modules, the cost of manufacturing the photovoltaic package of the invention can be drastically decreased owing to its simple structure, and thus the photovoltaic package of the invention can be effectively employed in various applications such as those of portable auxiliary batteries or promotional items.

### BRIEF DESCRIPTION OF DRAWINGS

FIG. 1 schematically shows the structure of a photovoltaic package according to a first embodiment of the present invention;

FIG. 2 shows a process of manufacturing the photovoltaic package according to the present invention;

FIG. 3 shows a processes of manufacturing the photovoltaic package according to the present invention;

FIG. 4 schematically shows the structure of a photovoltaic package according to a second embodiment of the present invention;

FIG. 5 schematically shows the structure of a photovoltaic package according to a third embodiment of the present invention;

FIG. 6 schematically shows the structure of a photovoltaic package according to a fourth embodiment of the present invention; and

FIG. 7 schematically shows the structure of a photovoltaic package according to a fifth embodiment of the present invention.

### DESCRIPTION OF SPECIFIC EMBODIMENTS

Hereinafter, a detailed description will be given of embodiments of the present invention with reference to the appended drawings.

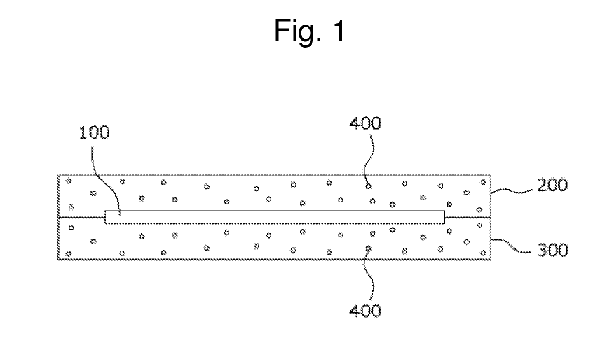

FIG. 1 schematically shows the structure of a photovoltaic package according to a first embodiment of the present invention.

As shown in FIG. 1, the photovoltaic package according to the present embodiment is configured to include an internally disposed photovoltaic cell 100 and a front sealing sheet 200 and a back sealing sheet 300 for sealing both sides of the photovoltaic cell.

The photovoltaic cell 100 performs photoelectric conversion to generate electric power, and any kind of solar cell may be applied without limitation. In particular, a thin-film solar cell, the thickness of which is low, may be applied. In the thin-film solar cell, the use of a compound semiconductor CZTS or CIGS solar cell enables the manufacturing cost to be further decreased. Such a thin-film solar cell is typically configured to include a light absorption layer for photoelectric conversion, a buffer layer, a front electrode and a back electrode, and the shape thereof is not particularly limited, and a specific description thereof is omitted. Furthermore, a conductor or the like is connected to the photovoltaic cell 100 so as to transfer the generated electrical energy to the outside, but is not depicted in the drawing as it remains the same in the other drawings.

The front sealing sheet 200 is disposed on the front side of the photovoltaic cell 100, which receives light, and the back sealing sheet 300 is disposed on the back side thereof, opposite the front side, and each of the front sealing sheet 200 and the back sealing sheet 300 contains moisture-absorbent particles 400 therein.

The materials for the front sealing sheet 200 and the back sealing sheet 300 are not particularly limited. However, since the front sealing sheet 200 is a portion in which light is incident on the photovoltaic cell 100, a material having high transparency is preferably used. When the photovoltaic cell 100 is a double-sided solar cell, the back side of which is also able to receive light, the back sealing sheet 300 is preferably formed of a material having high transparency.

Examples of material that have high transparency and facilitate sealing of the photovoltaic cell 100 may include an EVA (Ethylene-Vinyl Acetate) material serving as an encapsulant for a photovoltaic module. Typically, EVA, having low resistance to moisture, is merely used as an encapsulant for a lamination bonding process between the front sheet and the back sheet to protect the solar cell from moisture or the like during the manufacturing of the photovoltaic module, and is not utilized as a packing material that is exposed to the outside. However, in the present invention, since the moisture-absorbent particles 400 are dispersed in the front sealing sheet 200 and the back sealing sheet 300, desired properties thereof may be maintained for a considerable period of time even when using an EVA film having low moisture resistance. Furthermore, when the EVA film having the moisture-absorbent particles 400 dispersed therein is used for the front sealing sheet 200 and the back sealing sheet 300, the front sealing sheet 200 and the back sealing sheet 300 may be thermally adhered, whereby the photovoltaic cell 100 may be easily sealed.

The material for the moisture-absorbent particles 400 is not particularly limited, and may be exemplified by silica gel. The front sealing sheet 200 is a portion in which light is incident on the photovoltaic cell 100, and the front sealing sheet 200 preferably contains a moisture-absorbent material having high transparency. When the photovoltaic cell 100 is a double-sided solar cell, the back side of which is also able to receive light, the back sealing sheet 300 preferably contains a moisture-absorbent material having high transparency. Even when the moisture-absorbent material having high transparency is used, if the size of the moisture-absorbent particles 400 is too large, loss of incident light is increased. Hence, the size of the moisture-absorbent particles 400 is 100 μm or less, and preferably 10 μm or less. Although the lower limit of the size of the moisture-absorbent particles is not strictly limiting, the manufacturing cost may increase with a decrease in the particle size, and thus the particle size thereof is preferably selected within the appropriate range. Moreover, if the moisture-absorbent particles 400 are excessively dispersed in the front sealing sheet 200 and the back sealing sheet 300, loss of light is increased and the physical properties of the sealing sheet may decrease. On the other hand, if the moisture-absorbent particles 400 are dispersed in too small an amount, the photovoltaic cell is not protected from moisture for a sufficient period of time. Accordingly, when the amount of the moisture-absorbent particles 400 contained in the front sealing sheet 200 and the back sealing sheet 300 is 30% or less of the volume of the front sealing sheet 200 and the back sealing sheet 300, the physical properties of the sheet may not be deteriorated. Taking into consideration the efficiency of incident light, the amount thereof is preferably 10% or less of the volume of the front sealing sheet 200 and the back sealing sheet 300. On the other hand, the lower limit of the amount of the moisture-absorbent particles may be appropriately selected within a range exceeding zero, in consideration of the lifetime of the photovoltaic package, and is preferably 0.1% or more of the volume of the front sealing sheet 200 and the back sealing sheet 300.

Compared to a conventional photovoltaic module, which is manufactured for long-term use ranging from 10 years to tens of years, the photovoltaic package having the above configuration according to the present embodiment is suitable for mid-term use ranging from 1 year to several years or short-term use ranging from several weeks to 1 year.

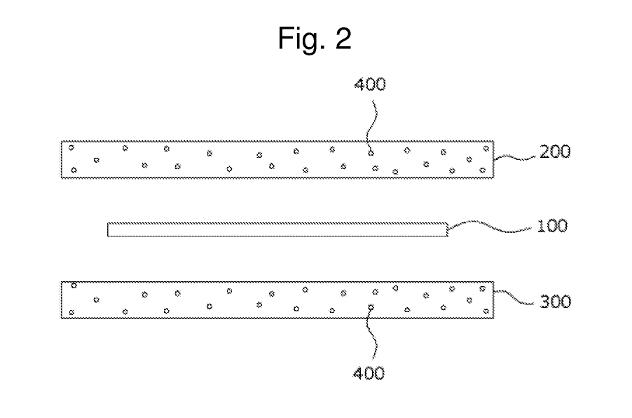

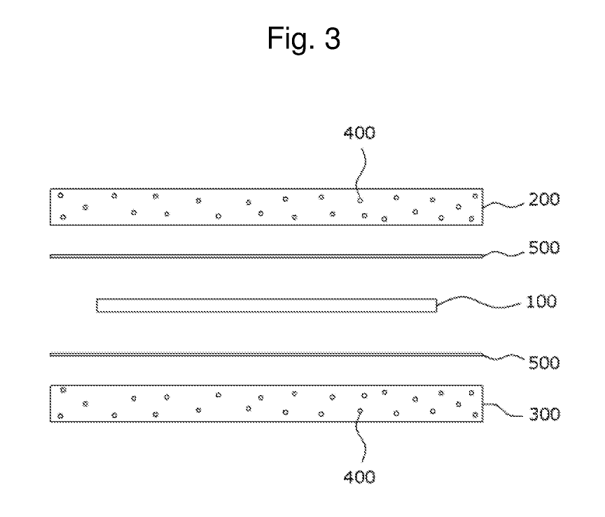

FIGS. 2 and 3 show the processes of manufacturing the photovoltaic package according to the present invention.

Specifically, a photovoltaic cell 100 and a front sealing sheet 200 and a back sealing sheet 300 containing therein moisture-absorbent particles 400 are provided. Here, the processes of manufacturing the front sealing sheet 200 and the back sealing sheet 300 are not particularly limited, and various methods for uniformly dispersing moisture-absorbent particles 400 may be applied. Furthermore, the process of manufacturing the photovoltaic cell 100 is not particularly limited, and a manufacturing process suitable for each of solar cells made of various materials may be applied without limitation.

Next, the photovoltaic cell 100 is positioned between the front sealing sheet 200 and the back sealing sheet 300, both of which contain therein the moisture-absorbent particles 400, whereby the back sealing sheet 300, the photovoltaic cell 100 and the front sealing sheet 200 are sequentially stacked and disposed.

Finally, the front sealing sheet 200 and the back sealing sheet 300 are adhered to each other, whereby the photovoltaic cell 100 is sealed therebetween.

Here, when the front sealing sheet 200 and the back sealing sheet 300 are formed of a material that enables thermal adhesion, such as an EVA material, an adhesive material is not additionally used, as shown in FIG. 2, and the front sealing sheet 200 and the back sealing sheet 300 are thermally adhered, thus sealing the photovoltaic cell 100.

On the other hand, when the front sealing sheet 200 and the back sealing sheet 300 are formed of a material that is unable to perform thermal adhesion, adhesive members 500 are interposed between the front sealing sheet 200 and the photovoltaic cell 100 and between the back sealing sheet 300 and the photovoltaic cell 100, whereby the photovoltaic cell 100 is sealed through the adhesive force between the adhesive members 500. Here, the adhesive member 500 may be a thermal adhesive member such as EVA, etc., or a tacky adhesive member.

The method of manufacturing the photovoltaic package according to the present invention includes stacking and adhering three layers, other than adhesive members, and may thus realize a very simple configuration and process, unlike the conventional method, in which five or more layers are laminated.

Below is a description of photovoltaic packages according to embodiments having structures different from the photovoltaic package according to the first embodiment shown in FIG. 1. Differences with the first embodiment are described herein, and description the same as that of the first embodiment is omitted. Also, a description of the manufacturing methods thereof is omitted because the processes of FIGS. 2 and 3 may be applied without change.

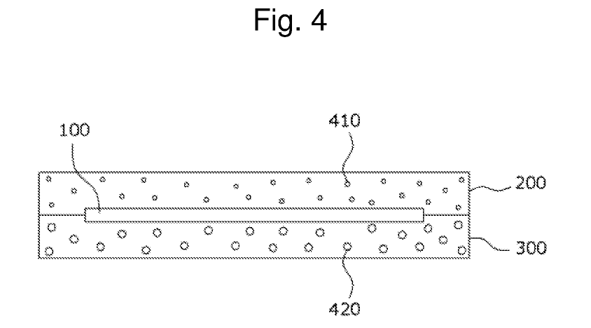

FIG. 4 schematically shows the structure of a photovoltaic package according to a second embodiment of the present invention.

The photovoltaic package according to the second embodiment is characterized in that the first moisture-absorbent particles 410 contained in the front sealing sheet 200 and the second moisture-absorbent particles 420 contained in the back sealing sheet 300 have particle sizes different from each other, unlike the first embodiment. Specifically, the particle size of the first moisture-absorbent particles 410 contained in the front sealing sheet 200 on which solar light is incident is smaller than the particle size of the second moisture-absorbent particles 420 contained in the back sealing sheet 300 at the opposite position.

The photovoltaic cell 100 thus configured is more suitable for use in a single-sided solar cell, only the front side of which is able to receive light, rather than a double-sided solar cell, the back side of which is also able to receive light. When the particle size of the second moisture-absorbent particles 420 dispersed in the back sealing sheet 300 is set to be larger, the moisture absorption capability of the photovoltaic package may be increased while maintaining the efficiency of incident light.

Preferably, the particle size of the second moisture-absorbent particles 420 contained in the back sealing sheet 300 is 500 μm or less, and the amount of the second moisture-absorbent particles 420 contained in the back sealing sheet 300 is 30% or less of the volume of the back sealing sheet 300.

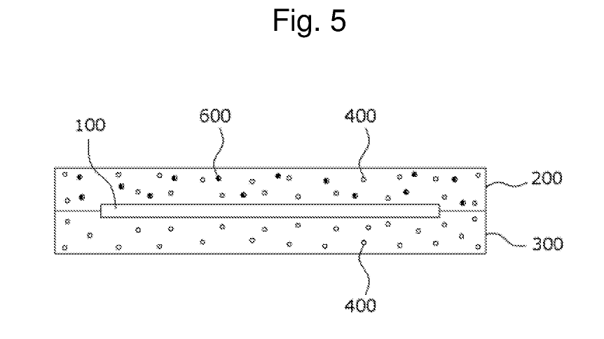

FIG. 5 schematically shows the structure of a photovoltaic package according to a third embodiment of the present invention.

Unlike the first embodiment, the photovoltaic package according to the third embodiment is characterized in that wavelength conversion particles 600, as well as the moisture-absorbent particles 400, are contained in the front sealing sheet 200.

The wavelength conversion particles 600 function such that incident light is wavelength-converted and emitted again, and may include a fluorescent material or a quantum-dot material. The photovoltaic cell 100 may exhibit a wavelength range within which power generation efficiency is high depending on the type of material thereof. Accordingly, when the wavelength conversion particles 600 for converting the wavelength of light into the corresponding wavelength range are dispersed, light in the wavelength range within which power generation efficiency is high may be incident in a larger amount on the photovoltaic cell 100, thereby increasing the power generation efficiency of the photovoltaic package. Here, when the total volume of the moisture-absorbent particles 400 and the wavelength conversion particles 600 dispersed in the front sealing sheet 200 is 30% or less of the volume of the front sealing sheet 200, the physical properties of the sheet may be maintained.

Although FIG. 5 illustrates the case where the wavelength conversion particles 600 are dispersed only in the front sealing sheet 200, such particles may also be dispersed in the back sealing sheet 300. This embodiment is more suitable for use in the case where a double-sided solar cell, the back side of which is also able to receive light, is provided as the photovoltaic cell 100.

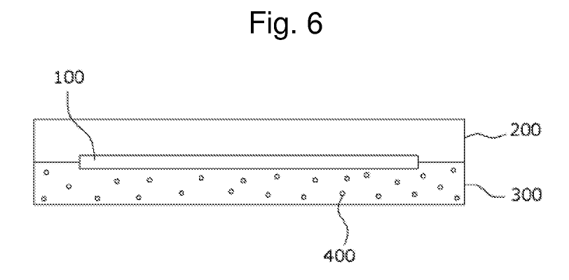

FIG. 6 schematically shows the structure of a photovoltaic package according to a fourth embodiment of the present invention.

The photovoltaic package according to the fourth embodiment is characterized in that the moisture-absorbent particles are not contained in the front sealing sheet 200, unlike the first embodiment.

The fourth embodiment is suitable for use in the case where a photovoltaic cell, the back side of which is unable to receive light, is applied. In order to increase the light-receiving efficiency of light incident through the front sealing sheet 200, the moisture-absorbent material is not dispersed in the front sealing sheet 200, and the moisture-absorbent particles 400 are dispersed in the back sealing sheet 300, whereby the photovoltaic cell 100 may be protected from moisture.

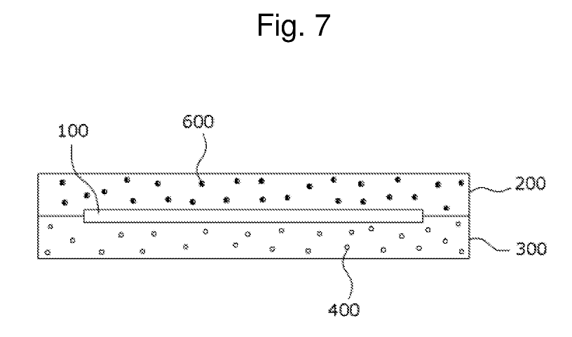

FIG. 7 schematically shows the structure of a photovoltaic package according to a fifth embodiment of the present invention.

The photovoltaic package according to the fifth embodiment is characterized in that only the wavelength conversion particles 600, other than the moisture-absorbent particles 400, are contained in the front sealing sheet 200, unlike the first embodiment.

Like the fourth embodiment, this embodiment is suitable for use in the case where a photovoltaic cell, the back side of which is unable to receive light, is applied. In order to increase the light-receiving efficiency of light incident through the front sealing sheet 200, as in the fourth embodiment, the moisture-absorbent material is not dispersed in the front sealing sheet 200, and the moisture-absorbent particles 400 are dispersed in the back sealing sheet 300, whereby the photovoltaic cell 100 may be protected from moisture. Here, because the wavelength conversion particles 600, functioning to convert the wavelength of light into a wavelength range within which the power generation efficiency of the photovoltaic cell 100 is high, are dispersed, light in the wavelength range within which the power generation efficiency is high may be incident in a larger amount on the photovoltaic cell 100, thereby increasing the power generation efficiency of the photovoltaic package.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Therefore, the scope of the present invention should be interpreted not by specific embodiments but by the accompanying claims, and it is to be understood that all technical ideas within the claims fall within the purview of the present invention.

What is claimed is:

1. A photovoltaic package, comprising:
a photovoltaic cell for producing electrical energy through photoelectric conversion;
a front sealing sheet disposed on a front side of the photovoltaic cell; and
a back sealing sheet disposed on a back side of the photovoltaic cell,
wherein at least one of the front sealing sheet and the back sealing sheet contains therein moisture-absorbent particles, and the front sealing sheet and the back sealing sheet are adhered to each other so that the photovoltaic cell is sealed.

2. The photovoltaic package of claim 1, wherein the moisture-absorbent particles are silica gel.

3. The photovoltaic package of claim 1, wherein the moisture-absorbent particles have a particle size of 100 μm or less.

4. The photovoltaic package of claim 1, wherein the moisture-absorbent particles contained in the front sealing sheet or the back sealing sheet have a volume corresponding to 30% or less of a volume of the front sealing sheet or the back sealing sheet.

5. The photovoltaic package of claim 1, wherein the moisture-absorbent particles are contained in both the front sealing sheet and the back sealing sheet, and
a particle size of the moisture-absorbent particles contained in the back sealing sheet is greater than a particle size of the moisture-absorbent particles contained in the front sealing sheet.

6. The photovoltaic package of claim 1, wherein the moisture-absorbent particles contained in the back sealing sheet have a particle size of 500 μm or less.

7. The photovoltaic package of claim 1, wherein at least one of the front sealing sheet and the back sealing sheet contains therein wavelength conversion particles.

8. The photovoltaic package of claim 1, wherein the moisture-absorbent particles are contained only in the back sealing sheet, and the front sealing sheet contains therein wavelength conversion particles.

9. The photovoltaic package of claim 1, wherein the front sealing sheet and the back sealing sheet comprise an EVA (Ethylene-Vinyl Acetate) material, and the front sealing sheet and the back sealing sheet are thermally adhered to each other.

10. A method of manufacturing a photovoltaic package configured such that a photovoltaic cell is packaged, the method comprising:
a preparation step of providing a photovoltaic cell for producing electrical energy through photoelectric conversion and a front sealing sheet and a back sealing sheet for sealing the photovoltaic cell;
a disposition step of sequentially stacking and disposing the back sealing sheet, the photovoltaic cell and the front sealing sheet; and
a sealing step of sealing the photovoltaic cell by adhering the back sealing sheet and the front sealing sheet to each other,
wherein in the preparation step, moisture-absorbent particles are added during at least one of manufacturing the front sealing sheet and manufacturing the back sealing sheet.

11. The method of claim 10, wherein in the sealing step, the back sealing sheet and the front sealing sheet are thermally adhered to each other.

12. The method of claim 11, wherein in the preparation step, the back sealing sheet and the front sealing sheet are manufactured using an EVA (Ethylene-Vinyl Acetate) material.

13. The method of claim 10, wherein in the sealing step, the back sealing sheet and the front sealing sheet are adhered using an adhesive member.

14. The method of claim 13, wherein the adhesive member is a thermal adhesive.

15. The method of claim 14, wherein the adhesive member is an EVA adhesive.

16. The method of claim 13, wherein the adhesive member is a tacky adhesive.
